(19) United States
(12) Patent Application Publication
(10) Pub. No.: US 2026/0339139 A1
(43) Pub. Date: Oct. 29, 2026

(54) DUAL-SIDED DISPLAY APPARATUS

(71) Applicant: AUO Corporation, Hsinchu City (TW)

(72) Inventors: Yan-Kai Wang, Hsinchu City (TW); Wang-Shuo Kao, Hsinchu City (TW); Chao-Wei Yeh, Hsinchu City (TW)

(73) Assignee: AUO Corporation, Hsinchu City (TW)

(21) Appl. No.: 19/372,257

(22) Filed: Oct. 28, 2025

(30) Foreign Application Priority Data
Apr. 25, 2025 (TW) 114115744

(51) Int. Cl. G02F 1/1333; G02F 1/13357; G02F 1/1343; H10H 29/30; H10H 29/856

(52) U.S. Cl. CPC G02F 1/133342; G02F 1/133603; G02F 1/13439; H10H 29/352; H10H 29/856

(57) ABSTRACT

A double-sided display apparatus includes a first substrate, a second substrate, a first reflective structure, a second reflective structure, a first light-emitting element, a second light-emitting element, a first flip-chip adhesive and a liquid crystal layer. The first reflective structure is disposed on a first region of the first substrate. The second reflective structure is disposed on a second region of the second substrate. The first light emitting element is disposed on the first reflective structure. The second light emitting element overlaps the second reflective structure. The first flip-chip adhesive covers the first light emitting element. The liquid crystal layer is disposed between the first flip-chip adhesive and a first region of the second substrate. The first flip-chip adhesive is disposed between the liquid crystal layer and the first light emitting element.

### CROSS-REFERENCE TO RELATED APPLICATION

This application claims the priority benefit of Taiwan application serial no. 114115744, filed on Apr. 25, 2025. The entirety of the above-mentioned patent application is hereby incorporated by reference herein and made a part of this specification.

### BACKGROUND

### Technical Field

The present disclosure relates to a display apparatus, and more particularly to a dual-sided display apparatus.

### Related Art

In vehicle applications, it is desirable for vehicle windows to be combined with transparent displays, allowing users inside the vehicle to switch the vehicle window to a transparent mode to view the scenery outside the vehicle, or switch to a display mode to view display information. When stopped or in special situations, it is also desirable for the vehicle window to be able to switch to an opaque mode to protect privacy. Traditional heat insulation films cannot provide switching and display functions. If polymer dispersed liquid crystal films are combined with vehicle windows, only two modes may be provided, and polymer dispersed liquid crystal films have the problem of higher driving voltage. In addition, traditional transparent displays are prone to moiré problems due to alignment of multiple substrates.

### SUMMARY

The present disclosure provides a dual-sided display apparatus with good performance.

The dual-sided display apparatus of the present disclosure includes a first substrate, a second substrate, a first reflection structure, a second reflection structure, a first light-emitting element, a second light emitting element, a first flip chip adhesive, and a liquid crystal layer. The first substrate has a first zone and a second zone outside the first zone. The second substrate has a first zone and a second zone outside the first zone. The first zone of the first substrate overlaps the first zone of the second substrate. The second zone of the first substrate overlaps the second zone of the second substrate. The first reflection structure is disposed on the first zone of the first substrate. The second reflection structure is disposed on the second zone of the second substrate. The first light-emitting element is disposed on the first reflection structure. The second light emitting element overlaps the second reflection structure. The first flip chip adhesive is disposed on the first reflection structure and covers the first light-emitting element. The liquid crystal layer is disposed between the first flip chip adhesive and the first zone of the second substrate. The first flip chip adhesive is disposed between the liquid crystal layer and the first light-emitting element.

### BRIEF DESCRIPTION OF THE DRAWINGS

FIG. 1 is a side view schematic diagram of a dual-sided display apparatus according to an embodiment of the present disclosure.

FIG. 2 is a side view schematic diagram of a dual-sided display apparatus according to another embodiment of the present disclosure.

FIG. 3 is a side view schematic diagram of a dual-sided display apparatus according to yet another embodiment of the present disclosure.

FIG. 4 is a side view schematic diagram of a dual-sided display apparatus according to still another embodiment of the present disclosure.

FIG. 5 is a top view schematic diagram of the first circuit structure, the second circuit structure, the first light-emitting element, and the second light emitting element of the dual-sided display apparatus of FIG. 4.

FIG. 6 is a side view schematic diagram of a dual-sided display apparatus according to an embodiment of the present disclosure.

FIG. 7 is a top view schematic diagram of the first circuit structure, the second circuit structure, the first light-emitting element, and the second light emitting element of the dual-sided display apparatus of FIG. 6.

### DESCRIPTION OF THE EMBODIMENTS

Reference will now be made in detail to exemplary embodiments provided in the disclosure, examples of which are illustrated in accompanying drawings. Wherever possible, identical reference numerals are used in the drawings and descriptions to refer to identical or similar parts.

It should be understood that when a device such as a layer, film, region or substrate is referred to as being “on” or “connected to” another device, it may be directly on or connected to another device, or intervening devices may also be present. In contrast, when a device is referred to as being “directly on” or “directly connected to” another device, there are no intervening devices present. As used herein, the term “connected” may refer to physical connection and/or electrical connection. Besides, if two devices are “electrically connected” or “coupled”, it is possible that other devices are present between these two devices.

The term “about,” “approximately,” or “substantially” as used herein is inclusive of the stated value and a mean within an acceptable range of deviation for the particular value as determined by people having ordinary skill in the art, considering the measurement in question and the error associated with measurement of the particular quantity (i.e., the limitations of the measurement system). For example, “about” may mean within one or more standard deviations, for example, ±30%, ±20%, ±10%, or +5% of the stated value. Moreover, a relatively acceptable range of deviation or standard deviation may be chosen for the term “about,” “approximately,” or “substantially” as used herein based on optical properties, etching properties or other properties, instead of applying one standard deviation across all the properties.

Unless otherwise defined, all terms (including technical and scientific terms) used herein have the same meaning as commonly understood by people of ordinary skill in the art. It will be further understood that terms, such as those defined in the commonly used dictionaries, should be interpreted as having a meaning that is consistent with their meaning in the context of the relevant art and the invention and will not be interpreted in an idealized or overly formal sense unless expressly so defined herein.

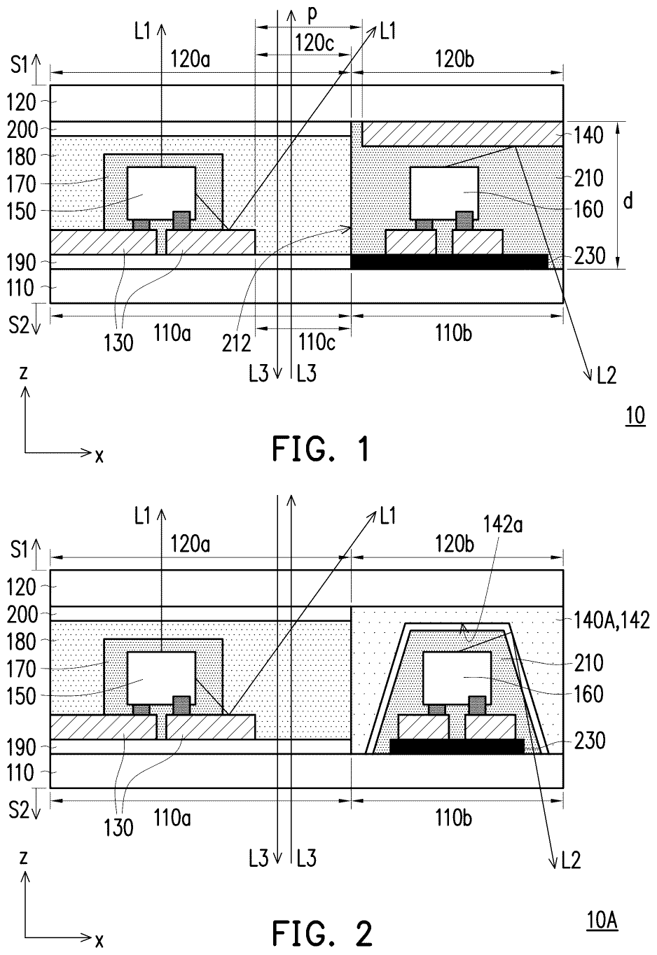

FIG. 1 is a side view schematic diagram of a dual-sided display apparatus according to an embodiment of the present disclosure. Referring to FIG. 1, the dual-sided display apparatus 10 includes a first substrate 110 and a second substrate 120 disposed opposite to the first substrate 110. The first substrate 110 has a first zone 110a and a second zone 110b outside the first zone 110a. The second substrate 120 has a first zone 120a and a second zone 120b outside the first zone 120a. The first zone 110a of the first substrate 110 overlaps the first zone 120a of the second substrate 120. The second zone 110b of the first substrate 110 overlaps the second zone 120b of the second substrate 120.

The dual-sided display apparatus 10 further includes a first reflection structure 130 and a second reflection structure 140. The first reflection structure 130 is disposed on the first zone 110a of the first substrate 110. The second reflection structure 140 is disposed on the second zone 120b of the second substrate 120. In some embodiments, the first reflection structure 130 is, for example, a metal reflective layer, but the present disclosure is not limited thereto. In some embodiments, the second reflection structure 140 is, for example, another metal reflective layer, but the present disclosure is not limited thereto.

The dual-sided display apparatus 10 further includes a first light-emitting element 150 and a second light emitting element 160. The first light-emitting element 150 is disposed on the first reflection structure 130. The second light emitting element 160 overlaps the second reflection structure 140. In some embodiments, the second light emitting element 160 may be selectively disposed on the second zone 110b of the first substrate 110, but the present disclosure is not limited thereto. In some embodiments, the first light-emitting element 150 and the second light emitting element 160 are, for example, micro light-emitting diodes (LED), but the present disclosure is not limited thereto.

The first light-emitting element 150 is configured to emit a first display light beam L1. A portion of the first display light beam L1 may pass through the second substrate 120 and be transmitted to the first side S1 of the dual-sided display apparatus 10. Another portion of the first display light beam L1 may be sequentially reflected by the first reflection structure 130 and pass through the second substrate 120 to be transmitted to the first side S1 of the dual-sided display apparatus 10. The second light emitting element 160 is configured to emit a second display light beam L2. At least a portion of the second display light beam L2 may be sequentially reflected by the second reflection structure 140 and pass through the first substrate 110 to be transmitted to the second side S2 of the dual-sided display apparatus 10.

For example, in some embodiments, the dual-sided display apparatus 10 may be applied in a vehicle, the first display light beam L1 emitted by the first light-emitting element 150 may be transmitted to the first side S1 of the dual-sided display apparatus 10 (for example: outside the vehicle), the second display light beam L2 emitted by the second light emitting element 160 may be transmitted to the second side S2 of the dual-sided display apparatus 10 (for example: inside the vehicle), to achieve the effect of dual-sided display. In addition, in some embodiments, an ambient light beam L3 may pass through the light transmission area 110c of the first substrate 110 and the light transmission area 120c of the second substrate 120 from the first side S1 or the second side S2 of the dual-sided display apparatus 10, thereby enabling the dual-sided display apparatus 10 to further present the visual effect of a transparent display.

The first reflection structure 130 is configured to reflect the first display light beam L1 toward the first side S1. The second reflection structure 140 is configured to reflect the second display light beam L2 toward the second side S2. The first reflection structure 130 and the second reflection structure 140 are preferably spaced at an appropriate distance, so that the first display light beam L1 and the second display light beam L2 can be smoothly reflected to the target side, reducing the probability of the first display light beam L1 and the second display light beam L2 being reflected to the non-target side. For example, in some embodiments, there is a first distance p between the first reflection structure 130 and the second reflection structure 140 in a first direction x parallel to the first substrate 110, there is a second distance d between the first substrate 110 and the second substrate 120 in a second direction z perpendicular to the first substrate 110, the liquid crystal layer 180 has a refractive index n₁, and

$$p \geq \sqrt{{p}^{2} + {d}^{2}} ( \frac{1}{{n}_{1}} ) .$$

The first light-emitting element 150 and the second light emitting element 160 are electrically connected to a first circuit structure (not shown in FIG. 1) and a second circuit structure (not shown in FIG. 1), respectively. The first circuit structure and the second circuit structure are configured to drive the first light-emitting element 150 and the second light emitting element 160, respectively. In some embodiments, each of the first circuit structure and the second circuit structure may include a pixel driving circuit (not shown) and a plurality of signal lines (not shown) electrically connected to the pixel driving circuit. In some embodiments, the pixel driving circuit includes, for example, a first transistor (not shown), a second transistor (not shown), and a capacitor (not shown), and the plurality of signal lines include, for example, a data line (not shown), a scan line (not shown), a power line (not shown), and a common line (not shown), wherein a first terminal of the first transistor is electrically connected to the data line, a control terminal of the first transistor is electrically connected to the scan line, a second terminal of the first transistor is electrically connected to a control terminal of the second transistor, a first terminal of the second transistor is electrically connected to the power line, the capacitor is electrically connected between the second terminal of the first transistor and the first terminal of the second transistor, a second terminal of the second transistor is electrically connected to a first electrode of one of the first light-emitting element 150 and the second light emitting element 160, and a second electrode of one of the first light-emitting element 150 and the second light emitting element 160 is electrically connected to the common line.

In some embodiments, the first light-emitting element 150 and the second light emitting element 160 may be selectively both disposed on the first substrate 110, the first substrate 110 may selectively have the first circuit structure and the second circuit structure, wherein the first light-emitting element 150 and the second light emitting element 160 may be electrically connected to the first circuit structure and the second circuit structure of the first substrate 110, respectively, but the present disclosure is not limited thereto.

The dual-sided display apparatus 10 further includes a first flip chip adhesive 170 and a liquid crystal layer 180. The first flip chip adhesive 170 is disposed on the first reflection structure 130 and covers the first light-emitting element 150. The liquid crystal layer 180 is disposed between the first zone 120a of the second substrate 120 and the first flip chip adhesive 170. The first flip chip adhesive 170 is disposed between the liquid crystal layer 180 and the first light-emitting element 150. The first light-emitting element 150 is disposed between the first flip chip adhesive 170 and the first zone 110a of the first substrate 110. For example, in some embodiments, the material of the first flip chip adhesive 170 may include polymethyl methacrylate (PMMA) or polycarbonate resin (PC), but the present disclosure is not limited thereto.

In some embodiments, the dual-sided display apparatus 10 further includes a first transparent electrode 190 and a second transparent electrode 200. The first transparent electrode 190 is disposed on the first zone 110a of the first substrate 110. The second transparent electrode 200 is disposed on the first zone 120a of the second substrate 120. The liquid crystal layer 180 and the first flip chip adhesive 170 are located between the first transparent electrode 190 and the second transparent electrode 200.

The first transparent electrode 190 and the second transparent electrode 200 are used to apply voltage to the liquid crystal layer 180. In some embodiments, according to whether the liquid crystal layer 180 is applied with voltage, the liquid crystal layer 180 may be switched to a transmission mode or a scattering mode. When the liquid crystal layer 180 is switched to the transmission mode, the ambient light beam L3 may pass through the dual-sided display apparatus 10, thereby causing the dual-sided display apparatus 10 to present a transparent mode. When the liquid crystal layer 180 is switched to the scattering mode, the ambient light beam L3 may be scattered by the liquid crystal layer 180, thereby causing the dual-sided display apparatus 10 to present an opaque mode to protect the privacy of users (for example: people in the vehicle). For example, in some embodiments, the liquid crystal layer 180 may include Polymer-dispersed Liquid Crystal (PDLC) or Polymer Network Liquid Crystal (PNLC), but the present disclosure is not limited thereto.

In some embodiments, the dual-sided display apparatus 10 further includes a second flip chip adhesive 210 covering the second light emitting element 160. The second flip chip adhesive 210 is located between the second reflection structure 140 and the second light emitting element 160. The second light emitting element 160 is located between the second flip chip adhesive 210 and the second zone 110b of the first substrate 110. The second flip chip adhesive 210 has a sidewall 212. In some embodiments, the sidewall 212 of the second flip chip adhesive 210 may contact the liquid crystal layer 180. For example, in some embodiments, the material of the second flip chip adhesive 210 may include polymethyl methacrylate (PMMA) or polycarbonate resin (PC), but the present disclosure is not limited thereto.

In some embodiments, the dual-sided display apparatus 10 further includes an absorption layer 230 disposed between the second light emitting element 160 and the second zone 110b of the first substrate 110. The absorption layer 230 may improve backside light leakage, that is, reduce the amount of the second display light beam L2 leaking to the first side S1.

It must be noted here that the following embodiments use the component reference numbers and partial content of the aforementioned embodiments, wherein the same reference numbers are used to represent the same or similar components, and the description of the same technical content is omitted. For the description of the omitted parts, reference may be made to the aforementioned embodiments, and the following embodiments will not be repeated.

FIG. 2 is a side view schematic diagram of a dual-sided display apparatus according to another embodiment of the present disclosure. The dual-sided display apparatus 10A of FIG. 2 is similar to the dual-sided display apparatus 10 of FIG. 1, and the main difference between them is that the second reflection structure 140A of FIG. 2 is different from the second reflection structure 140 of FIG. 1. Referring to FIG. 2, specifically, in this embodiment, the second reflection structure 140A includes a material layer 142, the material layer 142 has a depression 142a, and the second light emitting element 160 is located in the depression 142a. The second reflection structure 140A having the depression 142a is equivalent to a reflective light cup, which may reflect the second display light beam L2 emitted by the second light emitting element 160 toward the second side S2. In this embodiment, the refractive index of the second flip chip adhesive 210 is greater than the refractive index of the material layer 142 of the second reflection structure 140A. Thereby, the second display light beam L2 is easily totally reflected on the light-receiving surface of the second reflection structure 140A and transmitted toward the second side S2. In this embodiment, the material of the second reflection structure 140A is, for example, photoresist, but the present disclosure is not limited thereto.

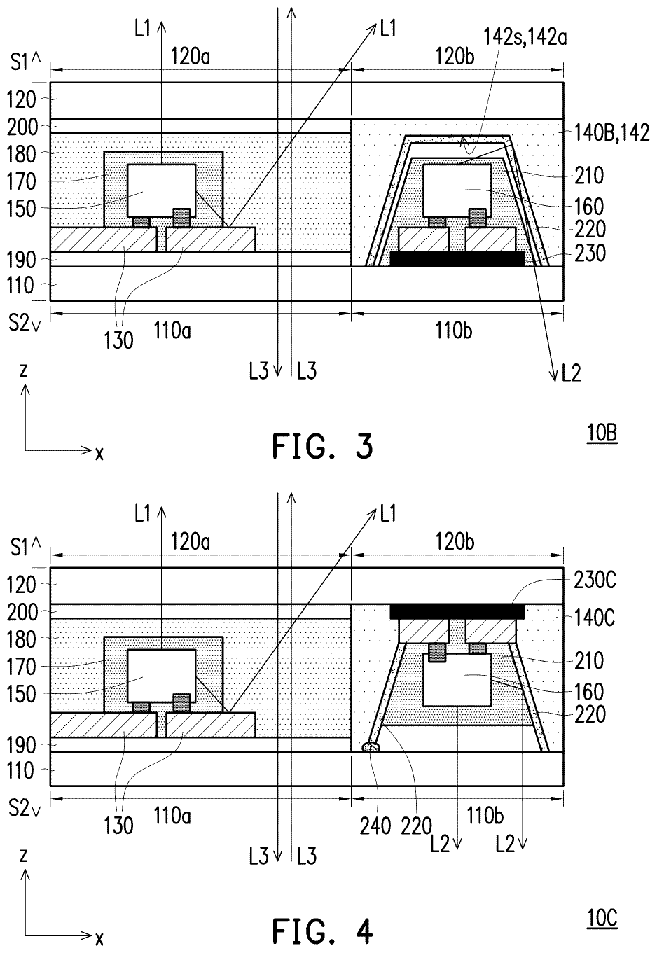

FIG. 3 is a side view schematic diagram of a dual-sided display apparatus according to yet another embodiment of the present disclosure. The dual-sided display apparatus 10B of FIG. 3 is similar to the dual-sided display apparatus 10A of FIG. 2. In the embodiment of FIG. 3, the second reflection structure 140B includes a material layer 142, the material layer 142 has a depression 142a, and the second light emitting element 160 is located in the depression 142a. It is a difference from the embodiment of FIG. 2 that in the embodiment of FIG. 3, the dual-sided display apparatus 10B further includes a reflective layer 220. The material layer 142 of the second reflection structure 140B has a first sidewall 142s defining the depression 142a. The reflective layer 220 is disposed on the first sidewall 142s and surrounds the second light emitting element 160. The second display light beam L2 emitted by the second light emitting element 160 may be reflected by the reflective layer 220 toward the second side S2 of the dual-sided display apparatus 10B.

FIG. 4 is a side view schematic diagram of a dual-sided display apparatus according to still another embodiment of the present disclosure. The dual-sided display apparatus 10C of FIG. 4 is similar to the dual-sided display apparatus 10B of FIG. 3. In the embodiment of FIG. 4, the second reflection structure 140C includes a material layer 142, the material layer 142 has a depression 142a, and the second light emitting element 160 is located in the depression 142a. It is a difference from the embodiment of FIG. 3 that in the embodiment of FIG. 4, the second light emitting element 160 and the absorption layer 230C are disposed on the second zone 120b of the second substrate 120. Since the second light emitting element 160 is disposed on the second substrate 120, a large portion of the second display light beam L2 emitted by the second light emitting element 160 may be directly transmitted toward the second side S2, thereby making the light extraction efficiency of the second light emitting element 160 favorable.

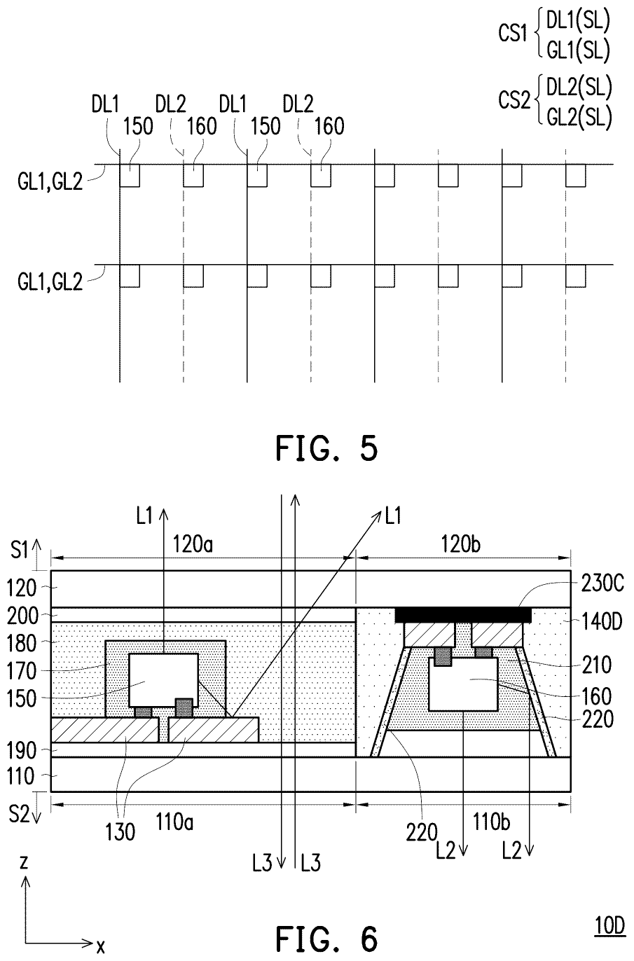

FIG. 5 is a top view schematic diagram of the first circuit structure, second circuit structure, first light-emitting element, and second light emitting element of the dual-sided display apparatus of FIG. 4. Referring to FIG. 4 and FIG. 5, in this embodiment, the first substrate 110 has a first circuit structure CS1 and a second circuit structure CS2, the first light-emitting element 150 is electrically connected to the first circuit structure CS1 of the first substrate 110, and the reflective layer 220 electrically connects the second light emitting element 160 and the second circuit structure CS2 of the first substrate 110. That is, the second light emitting element 160 disposed on the second substrate 120 may be electrically connected to the second circuit structure CS2 of the first substrate 110 through the reflective layer 220. In detail, in some embodiments, the reflective layer 220 may be electrically connected to the second circuit structure CS2 of the first substrate 110 through a conductor 240. For example, in some embodiments, the conductor 240 may include Au Ball and/or Ag glue, but the present disclosure is not limited thereto.

Referring to FIG. 4 and FIG. 5, in this embodiment, the first circuit structure CS1 and the second circuit structure CS2 respectively used to drive the first light-emitting element 150 and the second light emitting element 160 are both located in the first substrate 110, so the dual-sided display apparatus 10C will not exhibit moiré phenomenon due to interference between the first circuit structure CS1 and the second circuit structure CS2. In this embodiment, the signal lines SL of the first circuit structure CS1 may include a data line DL1 and a scan line GL1 electrically connected to the first light-emitting element 150, and the signal lines SL of the second circuit structure CS2 may include a data line DL2 and a scan line GL2 electrically connected to the second light emitting element 160. In some embodiments, the scan line GL1 and the scan line GL2 may be the same scan line, that is, the first light-emitting element 150 and the second light emitting element 160 may share the same scan line, but the present disclosure is not limited thereto.

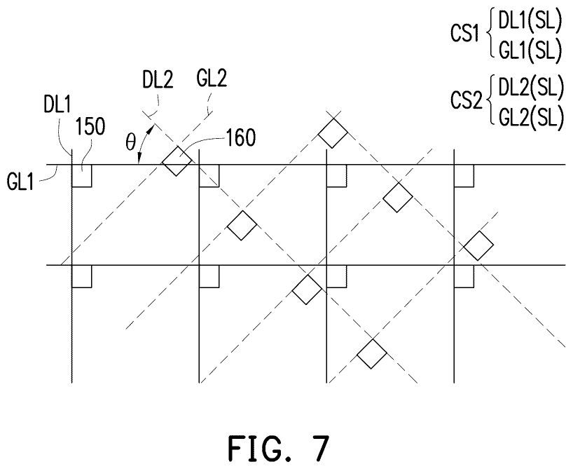

FIG. 6 is a side view schematic diagram of a dual-sided display apparatus according to an embodiment of the present disclosure. FIG. 7 is a top view schematic diagram of the first circuit structure, second circuit structure, first light-emitting element, and second light emitting element of the dual-sided display apparatus of FIG. 6. The dual-sided display apparatus 10D of FIG. 6 is similar to the dual-sided display apparatus 10B of FIG. 4. In the embodiment of FIG. 6, the second reflection structure 140D includes a material layer 142, the material layer 142 has a depression 142a, and the second light emitting element 160 is located in the depression 142a. Referring to FIG. 6 and FIG. 7, it is difference from the embodiment of FIG. 4 that in this embodiment, the first substrate 110 and the second substrate 120 respectively have a first circuit structure CS1 and a second circuit structure CS2, the first light-emitting element 150 is electrically connected to the first circuit structure CS1 of the first substrate 110, and the second light emitting element 160 is electrically connected to the second circuit structure CS2 of the second substrate 120.

In this embodiment, although the first circuit structure CS1 and the second circuit structure CS2 used to drive the first light-emitting element 150 and the second light emitting element 160 are respectively located in the first substrate 110 and the second substrate 120, since the signal line SL (e.g., the data line DL1) of the first circuit structure CS1 of the first substrate 110 and the signal line SL (e.g., the data line DL2) of the second circuit structure CS2 of the second substrate 120 have an angle θ therebetween, the moiré phenomenon formed due to interference between the first circuit structure CS1 and the second circuit structure CS2 is not easily perceived. For example, in this embodiment, the angle θ is substantially equal to 45°, but the present disclosure is not limited thereto.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A dual-sided display apparatus, comprising:
a first substrate having a first zone and a second zone outside the first zone;
a second substrate having a first zone and a second zone outside the first zone, wherein the first zone of the first substrate overlaps the first zone of the second substrate, and the second zone of the first substrate overlaps the second zone of the second substrate;
a first reflection structure disposed on the first zone of the first substrate;
a second reflection structure disposed on the second zone of the second substrate;
a first light-emitting element disposed on the first reflection structure;
a second light emitting element overlapping the second reflection structure;
a first flip chip adhesive disposed on the first reflection structure and covering the first light-emitting element; and
a liquid crystal layer disposed between the first flip chip adhesive and the first zone of the second substrate, wherein the first flip chip adhesive is disposed between the liquid crystal layer and the first light-emitting element.

2. The dual-sided display apparatus as claimed in claim 1, further comprising:
a first transparent electrode disposed on the first zone of the first substrate; and
a second transparent electrode disposed on the first zone of the second substrate;
wherein the liquid crystal layer and the first flip chip adhesive are located between the first transparent electrode and the second transparent electrode.

3. The dual-sided display apparatus as claimed in claim 1, wherein the second light emitting element is disposed on the second zone of the first substrate, the dual-sided display apparatus further comprising:
a second flip chip adhesive covering the second light emitting element, wherein the second flip chip adhesive is located between the second reflection structure and the second light emitting element.

4. The dual-sided display apparatus as claimed in claim 3, wherein a sidewall of the second flip chip adhesive contacts the liquid crystal layer.

5. The dual-sided display apparatus as claimed in claim 3, wherein there is a first distance p between the first reflection structure and the second reflection structure in a first direction parallel to the first substrate, there is a second distance d between the first substrate and the second substrate have in a second direction perpendicular to the first substrate, the liquid crystal layer has a refractive index n₁, and
$$p \geq \sqrt{{p}^{2} + {d}^{2}} ( \frac{1}{{n}_{1}} ) .$$

6. The dual-sided display apparatus as claimed in claim 1, wherein the second reflection structure comprises a material layer, the material layer has a depression, and the second light emitting element is located in the depression.

7. The dual-sided display apparatus as claimed in claim 6, further comprising:
a second flip chip adhesive covering the second light emitting element and located in the depression of the material layer, wherein a refractive index of the second flip chip adhesive is greater than a refractive index of the material layer.

8. The dual-sided display apparatus as claimed in claim 6, wherein the material layer of the second reflection structure has a first sidewall defining the depression, the dual-sided display apparatus further comprising:
a reflective layer disposed on the first sidewall and surrounding the second light emitting element.

9. The dual-sided display apparatus as claimed in claim 8, wherein the first substrate has a first circuit structure and a second circuit structure, the first light-emitting element is electrically connected to the first circuit structure of the first substrate, the second light emitting element is disposed on the second zone of the second substrate, and the reflective layer electrically connects the second light emitting element and the second circuit structure of the first substrate.

10. The dual-sided display apparatus as claimed in claim 9, wherein the first substrate and the second substrate respectively have a first circuit structure and a second circuit structure, the first light-emitting element is electrically connected to the first circuit structure of the first substrate, the second light emitting element is disposed on the second zone of the second substrate, the second light emitting element is electrically connected to the second circuit structure of the second substrate, a signal line of the first circuit structure of the first substrate and a signal line of the second circuit structure of the second substrate form an angle therebetween, and the angle is substantially equal to 45°.

11. A dual-sided display apparatus, comprising:
a first substrate having a first zone and a second zone outside the first zone;
a second substrate having a first zone and a second zone outside the first zone, wherein the first zone of the first substrate overlaps the first zone of the second substrate, and the second zone of the first substrate overlaps the second zone of the second substrate;
a first reflection structure disposed on the first zone of the first substrate;
a second reflection structure disposed on the second zone of the second substrate;
a first light-emitting element disposed on the first reflection structure;
a second light emitting element overlapping the second reflection structure; and
a liquid crystal layer disposed between the first zone of the first substrate and the first zone of the second substrate;
wherein the second reflection structure comprises a material layer, the material layer has a depression, and the second light emitting element is located in the depression.

12. The dual-sided display apparatus as claimed in claim 11, further comprising:
a first flip chip adhesive disposed on the first reflection structure and covering the first light-emitting element; and
a second flip chip adhesive covering the second light emitting element and located in the depression of the material layer, wherein the refractive index of the second flip chip adhesive is greater than the refractive index of the material layer.

13. The dual-sided display apparatus as claimed in claim 11, wherein the material layer of the second reflection structure has a first sidewall defining the depression, the dual-sided display apparatus further comprising:
a reflective layer disposed on the first sidewall and surrounding the second light emitting element.

14. The dual-sided display apparatus as claimed in claim 13, wherein the first substrate has a first circuit structure and a second circuit structure, the first light-emitting element is electrically connected to the first circuit structure of the first substrate, the second light emitting element is disposed on the second zone of the second substrate, and the reflective layer electrically connects the second light emitting element and the second circuit structure of the first substrate.

15. The dual-sided display apparatus as claimed in claim 14, wherein the first substrate and the second substrate respectively have a first circuit structure and a second circuit structure, the first light-emitting element is electrically connected to the first circuit structure of the first substrate, the second light emitting element is disposed on the second zone of the second substrate, the second light emitting element is electrically connected to the second circuit structure of the second substrate, a signal line of the first circuit structure of the first substrate and a signal line of the second circuit structure of the second substrate have an angle therebetween, and the angle is substantially equal to 45°.
